(19) United States
(12) Patent Application Publication
(10) Pub. No.: US 2012/0234387 A1
(43) Pub. Date: Sep. 20, 2012

(54) SOLAR CELL AND METHOD FOR MANUFACTURING THE SAME

(75) Inventors: Masato SAWADA, Kanagawa-ken (JP); Junji Sano, Kanagawa-ken (JP); Tomomichi Naka, Kanagawa-ken (JP); Naoaki Sakurai, Kanagawa-ken (JP)

(73) Assignee: KABUSHIKI KAISHA TOSHIBA, Tokyo (JP)

(21) Appl. No.: 13/364,839

(22) Filed: Feb. 2, 2012

(30) Foreign Application Priority Data
Mar. 14, 2011 (JP) 2011-055169

(51) Int. Cl. H01L 31/0203; H01L 31/18

(52) U.S. Cl. 136/259; 438/64; 257/E31.117

(57) ABSTRACT

According to one embodiment, a solar cell includes a first substrate, a second substrate, a first electrode, a second electrode, a support unit, a sealing unit, a permeation suppression unit, and an electrolyte fluid. The first electrode is provided on a major surface of the first substrate. The second electrode is provided on a major surface of the second substrate. The support unit is provided on the second electrode. The support unit is configured to support a sensitizing dye. The sealing unit is configured to seal a circumferential edge portion of the first substrate and a circumferential edge portion of the second substrate. The permeation suppression unit is provided around the support unit on an inner side of the sealing unit. The electrolyte fluid is provided on an inner side of the permeation suppression unit.

### CROSS-REFERENCE TO RELATED APPLICATIONS

This application is based upon and claims the benefit of priority from the prior Japanese Patent Application No. 2011-055169, filed on Mar. 14, 2011; the entire contents of which are incorporated herein by reference.

### FIELD

Embodiments described herein relate generally to a solar cell and method for manufacturing the same.

### BACKGROUND

There exist solar cells in which an electrolyte fluid is encapsulated between electrodes. For example, there exist a dye-sensitized solar cell and the like in which an electrolyte fluid and a layer made of titanium oxide and the like configured to support a sensitizing dye (also called a photosensitizing dye) are encapsulated between a pair of substrates on which electrodes are provided.

In such a solar cell, the sealing is performed using glass frit to improve durability and moisture resistance.

However, in the case where the sealing is performed by fusing the glass frit, there is a risk that the performance of the solar cell may degrade because impurities such as a gas, moisture, and the like are emitted when the glass frit is fused and may enter the interior of the solar cell.

### BRIEF DESCRIPTION OF THE DRAWINGS

FIG. 1 is a schematic cross-sectional view illustrating a solar cell according to a first embodiment.

FIGS. 2A to 2C are schematic cross-sectional views of processes, illustrating a method for manufacturing the solar cell according to a second embodiment.

### DETAILED DESCRIPTION

In general, according to one embodiment, a solar cell includes a first substrate, a second substrate, a first electrode, a second electrode, a support unit, a sealing unit, a permeation suppression unit, and an electrolyte fluid. The second substrate is provided to face the first substrate. The first electrode is provided on a major surface of the first substrate on a side facing the second substrate. The second electrode is provided on a major surface of the second substrate on a side facing the first substrate. The support unit is provided on the second electrode. The support unit is configured to support a sensitizing dye. The sealing unit includes a glass material. The sealing unit is provided between the first substrate and the second substrate. The sealing unit is configured to seal a circumferential edge portion of the first substrate and a circumferential edge portion of the second substrate. The permeation suppression unit is provided around the support unit on an inner side of the sealing unit. The electrolyte fluid is provided on an inner side of the permeation suppression unit.

Embodiments will now be described with reference to the drawings. Similar components in the drawings are marked with like reference numerals, and a detailed description is omitted as appropriate.

As an example hereinbelow, the case is illustrated where the solar cell is a dye-sensitized solar cell (also called a photosensitized solar cell).

### First Embodiment

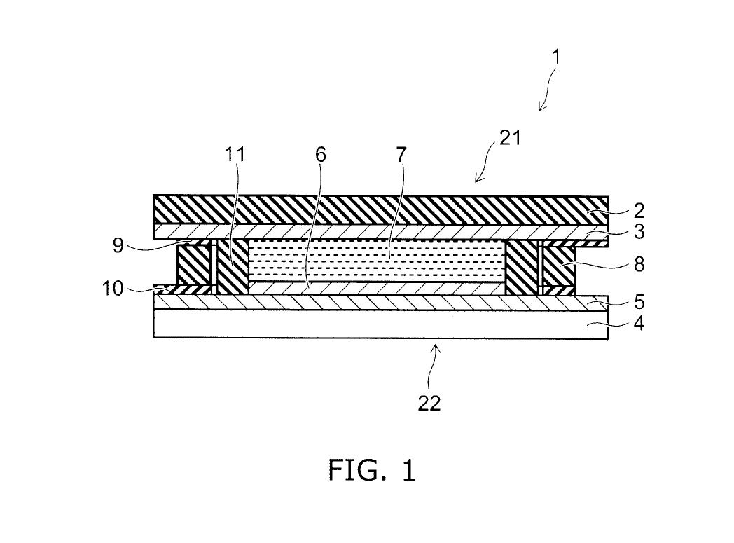

FIG. 1 is a schematic cross-sectional view illustrating a solar cell according to a first embodiment.

As illustrated in FIG. 1, the solar cell 1 includes a counter electrode unit 21, a photoelectrode unit 22, and a sealing unit 8.

The counter electrode unit 21 includes a first substrate 2, a first electrode 3, and a first bonding unit 9. The photoelectrode unit 22 includes a second substrate 4, a second electrode 5, a support unit 6, electrolyte fluid 7, a second bonding unit 10, and a permeation suppression unit 11. The electrolyte fluid 7 and the permeation suppression unit 11 may be provided in the counter electrode unit 21.

The first substrate 2 may have thermal stability with respect to the heat when performing the sealing described below, chemical resistance to the electrolyte fluid 7, and the like.

Although the second substrate 4 is transparent, the first substrate 2 may be transparent or non-transparent.

Therefore, the first substrate 2 may be formed using, for example, a metal such as aluminum and stainless steel, a resin, ceramics, glass, and the like. The first substrate 2 may be formed using the same transparent material as the second substrate 4.

The first electrode 3 has a film-like configuration and is provided on the major surface of the first substrate 2 on the side facing the second substrate 4.

The first electrode 3 is conductive and may have the thermal stability, the chemical resistance, etc., described above.

Although the second electrode 5 is transparent, the first electrode 3 may be transparent or non-transparent.

Therefore, the first electrode 3 may be formed using, for example, a metal such as platinum, gold, silver, copper, and aluminum, carbon, a conductive polymer, ITO (Indium Tin Oxide), and the like. The first electrode 3 may be formed using the same transparent material as the second electrode 5.

The second substrate 4 is provided to face the first substrate 2.

The second substrate 4 is transparent and may have the thermal stability, the chemical resistance, etc., described above.

The second substrate 4 may be formed using, for example, glass and the like.

The second electrode 5 has a film-like configuration and is provided on the major surface of the second substrate 4 on the side facing the first substrate 2.

The second electrode 5 may be transparent and conductive and may have thermal stability, chemical resistance, and the like.

The second electrode 5 may be formed using, for example, ITO, IZO (Indium Zinc Oxide), FTO (Fluorine-doped Tin Oxide), SnO₂, InO₃, and the like.

The support unit 6 is provided on the second electrode 5 on the central side of the second substrate 4. The support unit 6 may be configured to support a sensitizing dye. For example, the support unit 6 may include a porous body and a sensitizing dye supported by the porous body.

In such a case, the porous body may be formed using a metal oxide semiconductor such as TiO₂, ZnO, SnO₂, etc.

The sensitizing dye may be appropriately selected to have the desired light absorption band and absorption spectra necessary for the solar cell. The sensitizing dye may include, for example, an inorganic dye such as a Ru dye, an organic dye such as a coumarin dye, and the like.

The electrolyte fluid 7 is provided on the inner side of the permeation suppression unit 11 described below. The electrolyte fluid 7 may be, for example, an electrolyte fluid including iodine. In such a case, the electrolyte fluid 7 may include, for example, lithium iodide and iodine dissolved in a solvent such as acetonitrile and the like.

The sealing unit 8 is provided between the first substrate 2 and the second substrate 4 to seal the circumferential edge portion of the first substrate 2 and the circumferential edge portion of the second substrate 4.

In other words, the sealing unit 8 is provided around the interior of the solar cell 1 along the circumferential edges of the first substrate 2 and the second substrate 4 to seal the interior of the solar cell 1 by bonding the first substrate 2 side to the second substrate 4 side.

The sealing unit 8 may include a glass material.

The sealing unit 8 may be formed using, for example, glass frit having a paste form by mixing powdered glass, a binder such as an acrylic resin, an organic solvent, and the like.

The material of the powdered glass may include, for example, vanadate glass, bismuth oxide glass, and the like.

In such a case, the sealing unit 8 may be formed by coating glass frit in a paste form onto the portion to be sealed and by baking the glass frit. Then, the sealing can be performed by fusing the sealing unit 8 by heating the sealing unit 8. For example, the sealing can be performed by irradiating laser light onto the formed sealing unit 8 to fuse the portion of the sealing unit 8 irradiated with the laser light.

In such a case, there are cases where impurities such as a gas made of adsorbed moisture, remaining components such as the binder and the organic solvent, and the like are emitted from the sealing unit 8 to enter the interior of the solar cell when fusing the sealing unit 8.

In the case where such impurities such as the gas, the moisture, etc., enter the interior of the solar cell, there is a risk that performance degradation of the solar cell may occur due to degradation of the electrolyte fluid 7, the sensitizing dye, and the like.

In the case where the sealing unit 8 is fused to the first electrode 3 and the sealing unit 8 is fused to the second electrode 5, there is a risk that the first electrode 3 and the second electrode 5 undesirably may be altered.

For example, in the case where the first electrode 3 is formed from a metal and the like, there is a risk that the resistance value and the like of the first electrode 3 may fluctuate due to oxidization of the first electrode 3 and the like.

In the case where the second electrode 5 is formed from ITO and the like, there is a risk that the resistance value of the second electrode 5 may fluctuate due to alteration of the second electrode 5 and the like.

There is also a risk that the adhesion, the moisture resistance, the bonding strength, and the like may decrease between the sealing unit 8 and the first electrode 3 and between the sealing unit 8 and the second electrode 5.

Therefore, in this embodiment, the permeation suppression unit 11 is provided between the sealing unit 8 and the support unit 6 to suppress the permeation of the impurities such as the gas, the moisture, etc., which are emitted when the sealing unit 8 is heated, to the inner side of the permeation suppression unit 11.

The alteration of the first electrode 3 and the second electrode 5 when the sealing unit 8 is heated is suppressed by providing the first bonding unit 9 between the first electrode 3 and one end portion of the sealing unit 8 and by providing the second bonding unit 10 between the second electrode 5 and one other end portion of the sealing unit 8.

The first bonding unit 9, the second bonding unit 10, and the permeation suppression unit 11 will now be described further.

The first bonding unit 9 has a film-like configuration and is provided at a position to face the end surface of the sealing unit 8 of the first electrode 3.

The second bonding unit 10 has a film-like configuration and is provided at a position to face the end surface of the sealing unit 8 of the second electrode 5.

The first bonding unit 9 and the second bonding unit 10 may be formed from a material that can suppress the alteration of the first electrode 3 and the second electrode 5 when being fused to the sealing unit 8. It is favorable for the material to have good adhesion with the sealing unit 8, moisture resistance, bonding strength, and the like. When considering that the laser light is irradiated when fusing the sealing unit 8, it is favorable for the material to have low absorption of light of a wavelength of 700 nm or shorter.

For example, the first bonding unit 9 and the second bonding unit 10 may be formed from a metal oxide such as SiO₂, Al₂O₃, and TiO₂, a metal nitride such as SiN and AlN, a metal oxynitride such as SiON, and the like. In such a case, when considering the moisture resistance, it is favorable for the first bonding unit 9 and the second bonding unit 10 to be formed from a metal nitride.

Although the thickness dimensions of the first bonding unit 9 and the second bonding unit 10 are not particularly limited, the thickness dimensions may be at least enough to form a continuous film. When considering the occurrence of film stress, the increase of production costs, and the like, it is favorable for the thickness dimensions to be not more than a prescribed thickness dimension.

For example, the thickness dimensions of the first bonding unit 9 and the second bonding unit 10 may be not less than 10 nm and not more than 1 μm.

The permeation suppression unit 11 has a frame-like configuration and is provided around the support unit 6 on the inner side of the sealing unit 8. One end portion of the permeation suppression unit 11 contacts the first electrode 3; and one other end portion of the permeation suppression unit 11 contacts the second electrode 5. In such a case, the regions between the end portion of the permeation suppression unit 11 and the first electrode 3 and between the end portion of the permeation suppression unit 11 and the second electrode 5 may abut enough to be closely adhered and may be bonded using a bonding agent and the like such that the electrolyte fluid 7 does not leak out. Also, one end portion of the permeation suppression unit 11 may be bonded with a fluidic seal; and one other end portion may abut.

Although the case is illustrated where the end portions of the permeation suppression unit 11 contact the first electrode 3 and the second electrode 5, the end portions of the permeation suppression unit 11 may contact the first bonding unit 9 and the second bonding unit 10.

The permeation suppression unit 11 may be formed from a material that can suppress the permeation of the impurities such as the gas, the moisture, etc., that are emitted from the sealing unit 8. It is favorable for the permeation suppression unit 11 to include a material having chemical resistance with respect to the electrolyte fluid 7.

For example, the permeation suppression unit 11 may be formed from an epoxy resin, a silicon resin, an acrylic resin, a fluoric resin, a melamine resin, a phosphazene resin, a polyisobutylene resin, and the like.

The outer circumferential surface of the permeation suppression unit 11 may abut the inner circumferential surface of the sealing unit 8; or a gap may be provided.

In the case where a gap is provided between the outer circumferential surface of the permeation suppression unit 11 and the inner circumferential surface of the sealing unit 8, the gap may be used as a discharge location for the electrolyte fluid 7 that adheres to the end portion of the permeation suppression unit 11 when mounting the photoelectrode unit 22 side to the counter electrode unit 21 side as described below. Therefore, the occurrence of fusion defects and lower bonding strength of the sealing unit 8 can be suppressed because movement of the electrolyte fluid 7 adhered to the end portion of the permeation suppression unit 11 onto the end portion of the adjacent sealing unit 8 can be suppressed.

### Second Embodiment

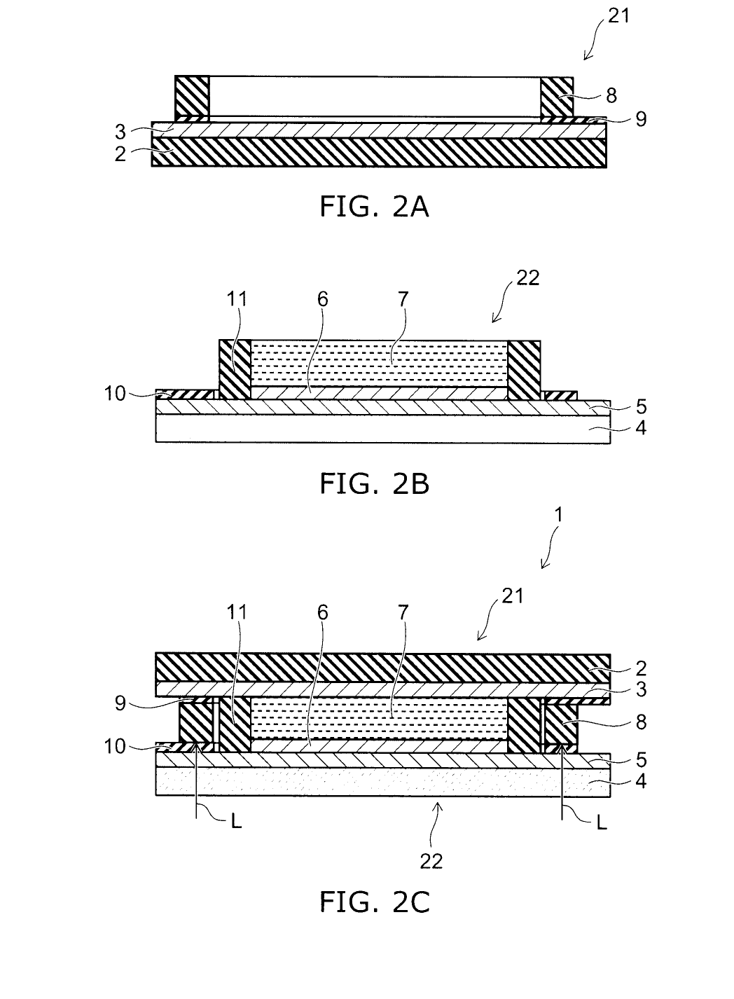

FIGS. 2A to 2C are schematic cross-sectional views of processes, illustrating a method for manufacturing the solar cell according to a second embodiment. FIG. 2A is a schematic cross-sectional view of a process, illustrating the formation on the counter electrode unit 21 side; FIG. 2B is a schematic cross-sectional view of a process, illustrating the formation on the photoelectrode unit 22 side; and FIG. 2C is a schematic cross-sectional view of a process, illustrating the appearance of the seal.

On the counter electrode unit 21 side as illustrated in FIG. 2A, first, the first electrode 3 is provided on one major surface of the first substrate 2.

For example, the first electrode 3 may be provided using various physical vapor deposition (PVD) methods such as vacuum vapor deposition and sputtering, various chemical vapor deposition (CVD) methods, a sol-gel method, and the like.

Then, the first bonding unit 9 is provided in a prescribed configuration on the first electrode 3.

For example, the first bonding unit 9 may be provided in a prescribed configuration by combining lithography, etching, and the like with various physical vapor deposition methods such as vacuum vapor deposition and sputtering, various chemical vapor deposition methods, a sol-gel method, and the like.

Then, the sealing unit 8 is provided on the counter electrode unit 21 side.

The method for providing the sealing unit 8 is, for example, as follows.

First, glass frit made by mixing powdered glass, a binder such as an acrylic resin, an organic solvent, and the like is coated in a paste form onto the first bonding unit 9 using screen printing, dispensing, and the like.

Then, the sealing unit 8 is provided by baking the coated glass frit using a heating furnace and the like.

On the photoelectrode unit 22 side as illustrated in FIG. 2B, first, the second electrode 5 is provided on one major surface of the second substrate 4.

Then, the second bonding unit 10 is provided in a prescribed configuration on the second electrode 5.

The methods for providing the second electrode 5 and the second bonding unit 10 may be similar to, for example, the methods for providing the first electrode 3 and the first bonding unit 9 described above.

Then, the support unit 6 is provided in a prescribed configuration on the second electrode 5.

The method for providing the support unit 6 is, for example, as follows.

First, a porous body is provided in a prescribed configuration on the second electrode 5 on the central side of the second substrate 4.

For example, the porous body may be provided in the prescribed configuration by coating a suspension including a metal oxide semiconductor such as porous TiO₂ and the like and by drying the suspension.

The porous body also can be provided in the prescribed configuration by combining lithography, etching, and the like with various physical vapor deposition methods such as vacuum vapor deposition and sputtering, various chemical vapor deposition methods, a sol-gel method, and the like.

Then, a sensitizing dye is loaded into the porous body.

For example, the sensitizing dye may be loaded into the porous body by making a solution in which the sensitizing dye is dissolved in a solvent such as alcohol, etc., and by immersing the porous body in this solution.

Then, the permeation suppression unit 11 is provided in a prescribed configuration at a position on the inner side of the sealing unit 8 around the support unit 6.

For example, the permeation suppression unit 11 may be provided by forming a member made of an epoxy resin using machining and the like and by bonding the member at a prescribed position on the second electrode 5 using a bonding agent and the like. The bonding agent may be, for example, a UV (ultraviolet)-curing bonding agent and the like.

The permeation suppression unit 11 also can be provided by coating an epoxy resin and the like dissolved into a solvent around the support unit 6 and by curing this solvent.

Then, the electrolyte fluid 7 is poured into the space defined by the permeation suppression unit 11 (the inner side of the permeation suppression unit 11).

Continuing as illustrated in FIG. 2C, the counter electrode unit 21 side is mounted to the photoelectrode unit 22 side to cover the photoelectrode unit 22 side; and sealing is performed by heating the sealing unit 8. For example, the sealing can be performed by heating the sealing unit 8 by irradiating laser light L from the photoelectrode unit 22 side toward the sealing unit 8.

Then, the permeation suppression unit 11 suppresses the permeation to the inner side of the permeation suppression unit 11 of the impurities such as the gas, the moisture, etc., that are emitted when the sealing unit 8 is heated in the process of sealing.

In such a case, even if the electrolyte fluid 7 is adhered to the end portion of the permeation suppression unit 11, the electrolyte fluid 7 can be discharged into the gap provided between the outer circumferential surface of the permeation suppression unit 11 and the inner circumferential surface of the sealing unit 8 before moving onto the end portion of the adjacent sealing unit 8 when mounting the counter electrode unit 21 side to the photoelectrode unit 22 side. Therefore, the occurrence of fusion defects and lower bonding strength of the sealing unit 8 can be suppressed.

Although the case is illustrated where the sealing unit 8 is provided on the counter electrode unit 21 side and the permeation suppression unit 11 and the electrolyte fluid 7 are provided on the photoelectrode unit 22 side, for example, the permeation suppression unit 11 and the electrolyte fluid 7 may be provided on the counter electrode unit 21 side; and the sealing unit 8 may be provided on the photoelectrode unit 22 side. Also, for example, the sealing unit 8, the permeation suppression unit 11, and the electrolyte fluid 7 may be provided on the counter electrode unit 21 side; and the sealing unit 8, the permeation suppression unit 11, and the electrolyte fluid 7 may be provided on the photoelectrode unit 22 side.

Although the case is illustrated where the electrolyte fluid 7 is provided on the inner side of the permeation suppression unit 11 prior to the sealing, the electrolyte fluid 7 also can be provided on the inner side of the permeation suppression unit 11 after the sealing is performed.

For example, a not-illustrated hole may be provided to pierce the first substrate 2 and the first electrode 3; the electrolyte fluid 7 may be poured through this hole after the sealing; and this hole may be plugged after pouring the electrolyte fluid 7.

The order in which the components described above are provided may be modified appropriately. For example, the second bonding unit 10 may be provided after the support unit 6 is provided, etc.

According to the embodiments described above, a solar cell in which performance degradation is suppressed and a method for manufacturing the same can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

For example, the configurations, the dimensions, the material properties, the dispositions, the numbers, and the like of the components included in the solar cell 1 are not limited to those illustrated and may be modified appropriately.

Although the case is illustrated where the solar cell is a dye-sensitized solar cell, this is not limited thereto. For example, the invention may be applied to a solar cell having a configuration in which a component provided in the interior of the solar cell degrades due to impurities emitted when a sealing unit is heated.

What is claimed is:

1. A solar cell, comprising:
a first substrate;
a second substrate provided to face the first substrate;
a first electrode provided on a major surface of the first substrate on a side facing the second substrate;
a second electrode provided on a major surface of the second substrate on a side facing the first substrate;
a support unit provided on the second electrode, the support unit being configured to support a sensitizing dye;
a sealing unit including a glass material provided between the first substrate and the second substrate, the sealing unit being configured to seal a circumferential edge portion of the first substrate and a circumferential edge portion of the second substrate;
a permeation suppression unit provided around the support unit on an inner side of the sealing unit; and
an electrolyte fluid provided on an inner side of the permeation suppression unit.

2. The solar cell according to claim 1, wherein the permeation suppression unit suppresses permeation of an emitted impurity to the inner side of the permeation suppression unit, the impurity being emitted when the sealing unit is heated.

3. The solar cell according to claim 1, wherein a gap is provided between an outer circumferential surface of the permeation suppression unit and an inner circumferential surface of the sealing unit.

4. The solar cell according to claim 1, wherein the permeation suppression unit includes at least one type selected from the group consisting of an epoxy resin, a silicon resin, an acrylic resin, a fluoric resin, a melamine resin, a phosphazene resin, and a polyisobutylene resin.

5. The solar cell according to claim 1, further comprising:
a first bonding unit provided between the first electrode and one end portion of the sealing unit; and
a second bonding unit provided between the second electrode and one other end portion of the sealing unit.

6. The solar cell according to claim 5, wherein:
the first bonding unit suppresses alteration of the first electrode when the sealing unit is heated; and
the second bonding unit suppresses alteration of the second electrode when the sealing unit is heated.

7. The solar cell according to claim 5, wherein a thickness dimension of the first bonding unit is not less than 10 nm and not more than 1 μm.

8. The solar cell according to claim 5, wherein a thickness dimension of the second bonding unit is not less than 10 nm and not more than 1 μm.

9. The solar cell according to claim 5, wherein the first bonding unit includes at least one type selected from the group consisting of metal oxide, metal nitride, and metal oxynitride.

10. The solar cell according to claim 5, wherein the second bonding unit includes at least one type selected from the group consisting of metal oxide, metal nitride, and metal oxynitride.

11. A method for manufacturing a solar cell, comprising:
providing a first electrode on one major surface of a first substrate;
providing a second electrode on one major surface of a second substrate;
providing a support unit on the second electrode, the support unit being configured to support a sensitizing dye in an interior of the support unit;
providing a sealing unit including a glass material on a circumferential edge portion of the first substrate on the first electrode side of the first substrate or on a circumferential edge portion of the second substrate on the second electrode side of the second substrate;
providing a permeation suppression unit around the support unit at a position between the sealing unit and the support unit on the first electrode or on the second electrode;
pouring an electrolyte fluid into an inner side of the permeation suppression unit; and
sealing the sealing unit by heating the sealing unit, permeation of an emitted impurity to the inner side of the permeation suppression unit being suppressed by the permeation suppression unit in the sealing, the impurity being emitted when the sealing unit is heated.

12. The method according to claim 11, wherein a gap is provided between an outer circumferential surface of the permeation suppression unit and an inner circumferential surface of the sealing unit.

13. The method according to claim 11, wherein the permeation suppression unit includes at least one type selected from the group consisting of an epoxy resin, a silicon resin, an acrylic resin, a fluoric resin, a melamine resin, a phosphazene resin, and a polyisobutylene resin.

14. The method according to claim 11, further comprising:
providing a first bonding unit at a position between the first electrode and one end portion of the sealing unit; and
providing a second bonding unit at a position between the second electrode and one other end portion of the sealing unit.

15. The method according to claim 14, wherein a thickness dimension of the first bonding unit is not less than 10 nm and not more than 1 μm.

16. The method according to claim 14, wherein a thickness dimension of the second bonding unit is not less than 10 nm and not more than 1 μm.

17. The method according to claim 14, wherein the first bonding unit includes at least one type selected from the group consisting of metal oxide, metal nitride, and metal oxynitride.

18. The method according to claim 14, wherein the second bonding unit includes at least one type selected from the group consisting of metal oxide, metal nitride, and metal oxynitride.

19. The method according to claim 11, further comprising:
forming a porous body in a prescribed configuration;
making a solution by dissolving the sensitizing dye in a solvent; and
forming the support unit by loading the sensitizing dye into the porous body by immersing the porous body in the solution.

20. The method according to claim 11, wherein:
the pouring of the electrolyte fluid into the inner side of the permeation suppression unit is performed after the sealing of the sealing unit by heating; and
the electrolyte fluid is poured through a hole provided in the first substrate or the second substrate.
